(19) United States
(12) Patent Application Publication
(10) Pub. No.: US 2025/0234679 A1
(43) Pub. Date: Jul. 17, 2025

(54) SEMICONDUCTOR LIGHT EMITTING DEVICE AND METHOD OF MANUFACTURING THE SAME

(71) Applicant: SAMSUNG ELECTRONICS CO., LTD., Suwon-si (KR)

(72) Inventors: Donggyu KIM, Suwon-si (KR); Bokyoung KIM, Suwon-si (KR); Seungmi SON, Suwon-si (KR); Dongmyung SHIN, Suwon-si (KR)

(73) Assignee: SAMSUNG ELECTRONICS CO., LTD., Suwon-si (KR)

(21) Appl. No.: 19/007,959

(22) Filed: Jan. 2, 2025

(30) Foreign Application Priority Data
Jan. 16, 2024 (KR) 10-2024-0006807

(51) Int. Cl. H10H 20/814; H10H 29/01; H10H 29/14; H10H 29/80; H10H 29/85

(52) U.S. Cl. CPC H10H 20/814; H10H 29/14; H10H 29/8325; H10H 29/857; H10H 29/011

(57) ABSTRACT

A semiconductor light emitting device may be provided that reduces product defects of a light emitting device by including a distributed Bragg reflector disposed at an edge of a light emitting structure, while improving the luminous efficiency of the light emitting device.

### CROSS-REFERENCE TO RELATED APPLICATION

This application is based on and claims priority under 35 USC § 119 to Korean Patent Application No. 10-2024-0006807, filed on Jan. 16, 2024, in the Korean Intellectual Property Office, the disclosure of which is incorporated by reference herein in its entirety.

### BACKGROUND

### 1. Field

Embodiments of the present disclosure relate to semiconductor light emitting devices and methods for manufacturing the same, and more particularly, to semiconductor light emitting devices having excellent light emitting characteristics and methods for manufacturing the same.

### 2. Brief Description of Background Art

Semiconductor light emitting devices are known as next-generation light sources due to their advantages such as long lifespan, low power consumption, fast response speed, and environmental friendliness compared to related art light sources. These devices have attracted attention as important light sources for use in various products such as backlights of lighting devices and display devices. Accordingly, semiconductor light emitting devices are required to have a structure with better light emitting characteristics and low product defects.

### SUMMARY

Embodiments of the present disclosure provide a semiconductor light emitting device having improved luminous efficiency.

According to embodiments of the present disclosure, a semiconductor light emitting device may be provided and include: a substrate; a light emitting structure including a first conductivity-type semiconductor layer, an active layer, and a second conductivity-type semiconductor layer sequentially stacked on the substrate; a transparent electrode layer on the second conductivity-type semiconductor layer; a first insulating layer on the transparent electrode layer and including a plurality of first through-holes; a first distributed Bragg reflector on the first insulating layer and including a plurality of second through-holes overlapping the plurality of first through-holes, wherein the first distributed Bragg reflector is apart from an edge of the light emitting structure; a second distributed Bragg reflector at the edge of the light emitting structure; a second insulating layer on the first distributed Bragg reflector and the second distributed Bragg reflector; and a reflective electrode layer on the second insulating layer such as to overlap the first distributed Bragg reflector, the reflective electrode layer connected to the transparent electrode layer through the plurality of first through-holes and the plurality of second through-holes.

According to embodiments of the present disclosure, a semiconductor light emitting device may be provided and include: a substrate; a light emitting structure including a first conductivity-type semiconductor layer, an active layer, and a second conductivity-type semiconductor layer that are stacked on the substrate, the light emitting structure further including a recess region in which portions of the first conductivity-type semiconductor layer, the active layer, and the second conductivity-type semiconductor layer are removed and a mesa region adjacent to the recess region; a transparent electrode layer on the second conductivity-type semiconductor layer; a first insulating layer on the transparent electrode layer and including a plurality of first through-holes in the mesa region; a first insulating multilayer film structure in the mesa region and on the first insulating layer, the first insulating multilayer film structure including a plurality of second through-holes overlapping the plurality of first through-holes; a second insulating multilayer film structure on the first insulating layer in the recess region; a second insulating layer covering an upper surface and side surfaces of the first insulating multilayer film structure and an upper surface and a side surface of the second insulating multilayer film structure; and a reflective electrode layer on the second insulating layer such as to overlap the first insulating multilayer film structure, the reflective electrode layer connected to the transparent electrode layer through the plurality of first through-holes and the plurality of second through-holes.

According to embodiments of the present disclosure, a semiconductor light emitting device may be provided and include: a substrate; a light emitting structure including a first conductivity-type semiconductor layer, an active layer, and a second conductivity-type semiconductor layer that are stacked on the substrate, the light emitting structure further including a recess region in which portions of the first conductivity-type semiconductor layer, the active layer, and the second conductivity-type semiconductor layer are removed and a mesa region adjacent to the recess region; a transparent electrode layer on the second conductivity-type semiconductor layer; a first insulating layer on the transparent electrode layer and including a plurality of first through-holes; a first distributed Bragg reflector on the first insulating layer and including a plurality of second through-holes overlapping the plurality of first through-holes, wherein the first distributed Bragg reflector is apart from an edge of the light emitting structure; a second distributed Bragg reflector on the first insulating layer and at the edge of the light emitting structure; a second insulating layer on the first distributed Bragg reflector and the second distributed Bragg reflector; a reflective electrode layer on the second insulating layer such as to overlap the first distributed Bragg reflector, the reflective electrode layer connected to the transparent electrode layer through the plurality of first through-holes and the plurality of second through-holes; a third insulating layer on the second insulating layer and the reflective electrode layer; a first connection electrode contacting and electrically connected to the first conductivity-type semiconductor layer through the first insulating layer, the second insulating layer, and the third insulating layer; and a second connection electrode contacting the reflective electrode layer and electrically connected to the second conductivity-type semiconductor layer through the third insulating layer.

The problems solved by embodiments of the present disclosure are not limited to the problems mentioned above, and other problems solved by embodiments of the present disclosure that are not mentioned will be clearly understood by those skilled in the art from the description below.

### BRIEF DESCRIPTION OF THE DRAWINGS

Embodiments will be more clearly understood from the following detailed description taken in conjunction with the accompanying drawings in which:

FIG. 1 is a plan view illustrating components of a semiconductor light emitting device according to an embodiment;

FIG. 2 is a cross-sectional view taken along line I-I′ of FIG. 1;

FIG. 3 is an enlarged view of a portion A1 of FIG. 2;

FIG. 4 is an enlarged view of a portion A2 of FIG. 2;

FIG. 5 is an enlarged view of a portion A3 of FIG. 2;

FIG. 6 is a flowchart illustrating a method of manufacturing a semiconductor light emitting device according to an embodiment;

FIGS. 7 to 14 are cross-sectional views illustrating a sequential process of a method of manufacturing a semiconductor light emitting device according to an embodiment;

FIG. 15 is a block diagram illustrating a configuration of a light source module including a semiconductor light emitting device according to an embodiment;

FIG. 16 is a perspective view illustrating a lighting device including a semiconductor light emitting device according to an embodiment;

FIG. 17 is a perspective view illustrating a flat lighting device including a light source module including a semiconductor light emitting device according to an embodiment;

FIG. 18 is an exploded perspective view illustrating a lighting device including a light source module including a semiconductor light emitting device according to an embodiment;

FIG. 19 is an exploded perspective view illustrating a bar-type lighting device including a light source module including a semiconductor light emitting device according to an embodiment;

FIG. 20 is an exploded perspective view illustrating a lighting device including a light source module including a semiconductor light emitting device according to an embodiment;

FIG. 21 is a schematic diagram illustrating an indoor lighting control network system including a light source module including a semiconductor light emitting device according to an embodiment; and

FIG. 22 is a schematic diagram illustrating a network system including a light source module including a semiconductor light emitting device according to an embodiment.

### DETAILED DESCRIPTION

Hereinafter, non-limiting example embodiments of the present disclosure are described in detail with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

In this specification, terms, such as “front” and “back,” are used to distinguish relative positions of components, and embodiments of the present disclosure are not limited by these terms. Accordingly, terms, such as “front” and “back,” may be replaced with other terms, such as “top” and “bottom,” which may be used to describe the components of the specification.

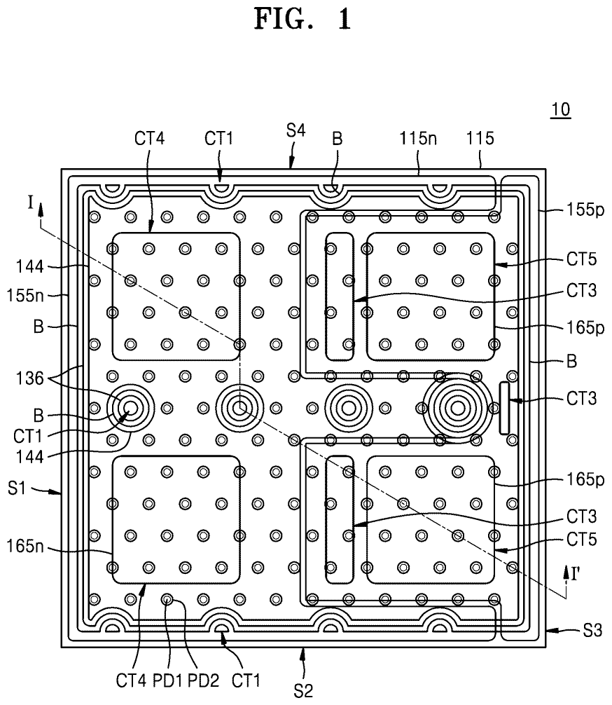

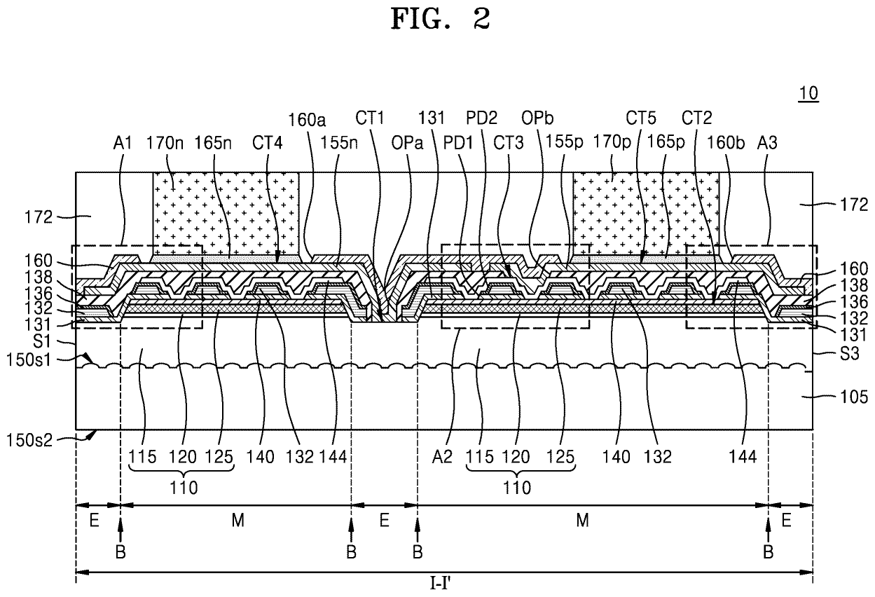

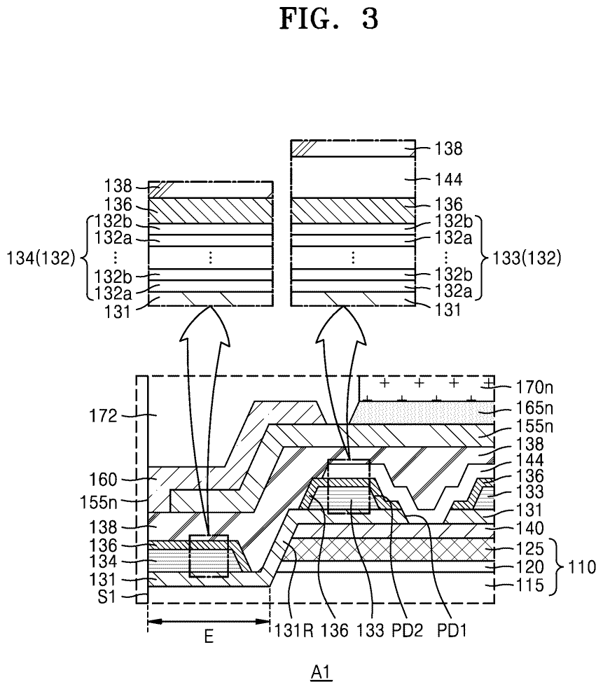

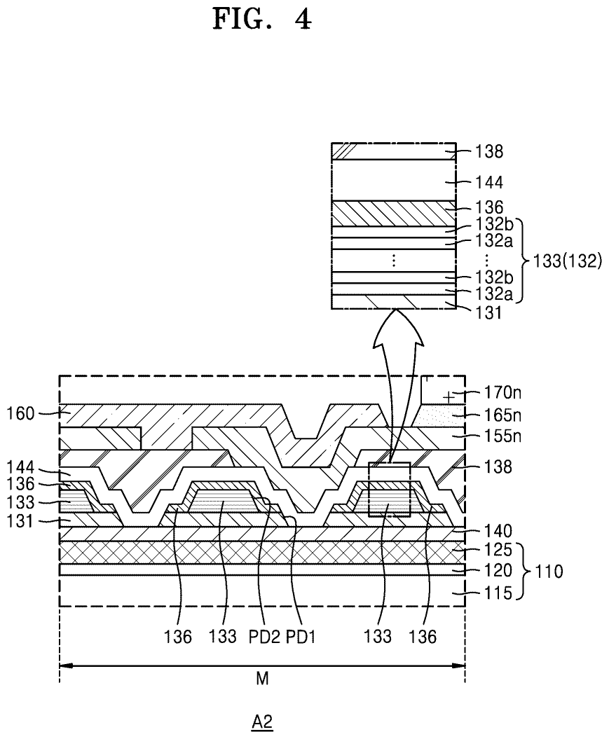

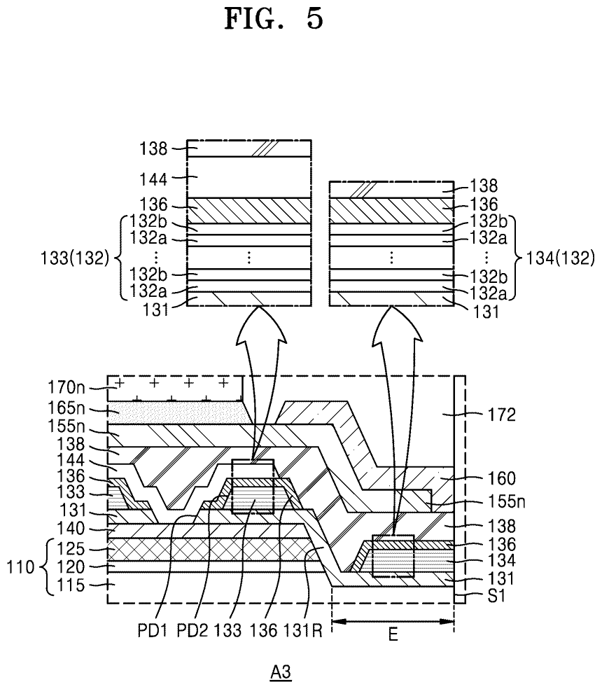

FIG. 1 is a plan view illustrating components of a semiconductor light emitting device 10 according to an embodiment. FIG. 2 is a cross-sectional view taken along line I-I′ of FIG. 1. FIG. 3 is an enlarged view of a portion A1 of FIG. 2. FIG. 4 is an enlarged view of a portion A2 of FIG. 2. FIG. 5 is an enlarged view of a portion A3 of FIG. 2.

Referring to FIGS. 1 to 5 together, the semiconductor light emitting device 10 may include a substrate 105, a light emitting structure 110, a first insulating layer 131, an insulating multilayer film structure 132, a second insulating layer 136, a third insulating layer 138, a fourth insulating layer 160, a transparent electrode layer 140, a reflective electrode layer 144, a first connection electrode 155n, a second connection electrode 155p, a first electrode pad 165n, a second electrode pad 165p, a first solder pillar 170n, and a second solder pillar 170p.

The substrate 105 may have a front surface 105s1 and a rear surface 105s2. The substrate 105 may be a substrate for semiconductor growth and may include an insulating semiconductor material, such as sapphire, Si, SiC, MgAl₂O₄, MgO, LiAlO₂, LiGaO₂, GaN, etc. Sapphire may have electrically insulating properties, may be a crystal with hexa-rhombo symmetry, and may be used as a substrate for growing nitride semiconductor.

In some embodiments, the front surface 105s1 of the substrate 105 may have an uneven structure, and the uneven structure may improve the crystallinity and light emission efficiency of semiconductor layers constituting the light emitting structure 110. The uneven structure of the front surface 105s1 of the substrate 105 is illustrated as having a dome-like convex shape, but is not limited thereto. For example, the uneven structure of the front surface 105s1 of the substrate 105 may have various shapes, such as squares and triangles. In addition, the uneven structure on the front surface 105s1 of the substrate 105 may be formed selectively or may be omitted.

In some embodiments, the substrate 105 may be removed, according to an embodiment. For example, the substrate 105 may be provided as a growth substrate for growing the light emitting structure 110 and then removed through a separation process. The substrate 105 may be separated from the light emitting structure 110 through a method, such as laser lift off (LLO) or chemical lift off (CLO).

According to embodiments, a buffer layer may be further provided on the front surface 105s1 of the substrate 105. The buffer layer may be used to alleviate lattice defects in a semiconductor layer grown on the substrate 105 and may include an undoped semiconductor layer including nitride or the like. The buffer layer may include GaN, AlN, InGaN, etc., and may grow to have a thickness of tens to hundreds of angstroms (Å) at a low temperature of about 500° C. to about 600° C. Here, “undoped” means that the semiconductor layer is not subjected to a separate impurity doping process. However, this buffer layer may be omitted according to an embodiment.

The light emitting structure 110 may be disposed on the front surface 105s1 of the substrate 105. The light emitting structure 110 may include a first conductivity-type semiconductor layer 115, an active layer 120, and a second conductivity-type semiconductor layer 125.

The first conductivity-type semiconductor layer 115 may be formed by growing from the front surface 105s1 of the substrate 105. The first conductivity-type semiconductor layer 115 may include a semiconductor doped with n-type impurities and may be an n-type nitride semiconductor layer.

In a plan view, the first conductivity-type semiconductor layer 115 may have a square shape. The first conductivity-type semiconductor layer 115 may have a first edge S1, a second edge S2, a third edge S3, and a fourth edge S4. Accordingly, the first edge S1 and the third edge S3 may be located on opposite sides of each other, and the second edge S2 and the fourth edge S4 may be located on opposite sides of each other.

The second conductivity-type semiconductor layer 125 may include a semiconductor doped with p-type impurities and may be a p-type nitride semiconductor layer. In some embodiments, the first conductivity-type semiconductor layer 115 and the second conductivity-type semiconductor layer 125 may be interchanged in position to be stacked according to an embodiment. The first conductivity-type semiconductor layer 115 and the second conductivity-type semiconductor layer 125 may have a composition formula of AlₓIn_{y}Ga_{(1-x-y)}N (here, 0≤x<1, 0≤y<1, 0≤x+y<1), and, for example, GaN, AlGaN, InGaN, and AlInGaN may correspond thereto.

The active layer 120 may be located between the first conductivity-type semiconductor layer 115 and the second conductivity-type semiconductor layer 125. The active layer 120 may emit light having a preset energy by recombination of electrons and holes when the semiconductor light emitting device 10 operates. The active layer 120 may include a material having an energy band gap smaller than an energy band gap of the first conductivity-type semiconductor layer 115 and the second conductivity-type semiconductor layer 125. For example, when the first conductivity-type semiconductor layer 115 and the second conductivity-type semiconductor layer 125 are GaN-based compound semiconductors, the active layer 120 may include an InGaN-based compound semiconductor having an energy band gap smaller than an energy band gap of GaN.

In addition, the active layer 120 may have a multiple quantum well (MQW) structure in which quantum well layers and quantum barrier layers are alternately stacked, for example, an InGaN/GaN structure. However, embodiments of the present disclosure are not limited thereto, and the active layer 120 may have a single quantum well (SQW) structure.

The light emitting structure 110 may include a recess region E in which portions of the second conductivity-type semiconductor layer 125, the active layer 120, and the first conductivity-type semiconductor layer 115 are etched and a mesa region M around the recess region E. A boundary region B may refer to a boundary between the recess region E and the mesa region M. An upper surface of the mesa region M may have a higher vertical level than a vertical level of an upper surface of the recess region E. In some embodiments, the mesa region M may have a shape that gradually narrows from the bottom to the top. Accordingly, the mesa region M may have an inclined side.

In some embodiments, a portion of the upper surface of the recess region E may be defined as a first contact region CT1. In some embodiments, at least a portion of an upper surface of the mesa region M may be defined as a second contact region CT2.

The mesa region M may be apart from the first edge S1, the second edge S2, the third edge S3, and the fourth edge S4, and the recess region E may be located between the mesa region M and the first edge S1, the second edge S2, the third edge S3, and the fourth edge S4. Portions of the recess region E apart from each other in a circular shape may be further located in a central portion of the light emitting structure 110.

The transparent electrode layer 140 may be disposed on the second conductivity-type semiconductor layer 125 of the light emitting structure 110. The transparent electrode layer 140 may be located in the second contact region CT2 of the second conductivity-type semiconductor layer 125 and electrically connected to the second conductivity-type semiconductor layer 125.

The transparent electrode layer 140 may include at least one selected from among indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂, and zinc magnesium oxide (Zn₍₁₋ₓ₎MgₓO) (0≤x≤1).

The first insulating layer 131 may be disposed on the transparent electrode layer 140. The first insulating layer 131 may cover a portion of the first conductivity-type semiconductor layer 115 and a portion of the second conductivity-type semiconductor layer 125. The first insulating layer 131 may include a plurality of first through-holes PD1 located in the mesa region M. The first insulating layer 131 may partially cover the transparent electrode layer 140 in the mesa region M.

Here, the plurality of first through-holes PD1 are illustrated as being arranged in a hexagonal dense lattice shape, but embodiments of the present disclosure are not limited thereto. For example, the plurality of first through-holes PD1 may be arranged in various shapes, such as a square grid shape.

In addition, the plurality of first through-holes PD1 are illustrated as having a circular cross-section, but are not limited thereto. For example, the plurality of first through-holes PD1 may have a polygonal or ring-shaped cross-section.

In some embodiments, the transparent electrode layer 140 may have a plurality of through-holes arranged to be offset from the plurality of first through-holes PD1. In this case, the first insulating layer 131 may fill the plurality of through-holes of the transparent electrode layer 140.

The first insulating layer 131 may include, for example, silicon oxide or silicon nitride, and may include, for example, SiO₂, SiN, SiOₓN_{y}, Si₃N₄, etc. The first insulating layer 131 may improve adhesion of the insulating multilayer film structure 132 to be described below.

The insulating multilayer film structure 132 may be used as a reflective structure to reflect light, emitted from the active layer 120 in a direction away from the substrate 105, and redirect the light back toward the substrate 105.

The insulating multilayer film structure 132 may be a structure in which a first insulating film 132a and a second insulating film 132b respectively having a first refractive index and a second refractive index, which are different refractive indices, are alternately stacked. The insulating multilayer film structure 132 may be provided as a distributed Bragg reflector (DBR) appropriately adjusting the refractive indices and thicknesses of the first insulating film 132a and the second insulating film 132b.

The insulating multilayer film structure 132 may include silicon oxide or silicon nitride having insulating properties and light transmitting properties and may include, for example, SiO₂, SiN, SiOₓN_{y}, TiO₂, Si₃N₄, Al₂O₃, TiN, AlN, ZrO₂, TiAlN, TiSiN, etc., but is not limited thereto.

In some embodiments, the insulating multilayer film structure 132 may have a structure in which the first insulating film 132a including SiO₂ and the second insulating film 132b including TiO₂ are alternately stacked. The lowermost surface of the insulating multilayer film structure 132 may be in contact with the first insulating layer 131, and the uppermost surface of the insulating multilayer film structure 132 may be in contact with the second insulating layer 136. For example, the first insulating film 132a including SiO₂ may define the lowermost surface of the insulating multilayer film structure 132, and the second insulating film 132b including TiO₂ may define the uppermost surface of the insulating multilayer film structure 132.

In the semiconductor light emitting device 10 of embodiments of the present disclosure, the insulating multilayer film structure 132 may include a first insulating multilayer film structure 133 and a second insulating multilayer film structure 134. According to their functions, the first insulating multilayer film structure 133 may be referred to as a first distributed Bragg reflector, and the second insulating multilayer film structure 134 may be referred to as a second distributed Bragg reflector.

First, the first insulating multilayer film structure 133 is described as follows. The first insulating multilayer film structure 133 may include a plurality of second through-holes PD2 arranged to overlap the plurality of first through-holes PD1 on the first insulating layer 131, and may be apart from the edge of the light emitting structure 110.

That is, the first insulating multilayer film structure 133 may be disposed on the first insulating layer 131 to entirely cover the light emitting structure 110. In other words, the first insulating multilayer film structure 133 may be disposed to cover the mesa region M on the first insulating layer 131.

The first insulating multilayer film structure 133 may include a plurality of second through-holes PD2 located in the mesa region M. The plurality of second through-holes PD2 may be arranged to overlap the plurality of first through-holes PD1 located in the first insulating layer 131. Therefore, the reflective electrode layer 144 disposed above the first insulating multilayer film structure 133 may be connected to the transparent electrode layer 140 through the plurality of first through-holes PD1 and the plurality of second through-holes PD2.

Next, the second insulating multilayer film structure 134 is described as follows. The second insulating multilayer film structure 134 may be located on the first insulating layer 131 in the recess region E, which is at the edge of the light emitting structure 110.

That is, the second insulating multilayer film structure 134 may be located horizontally side by side with the light emitting structure 110 on the first insulating layer 131 In other words, a level of the first insulating multilayer film structure 133 in a vertical direction may be higher than a level of the second insulating multilayer film structure 134 in the vertical direction.

The second insulating multilayer film structure 134 may be located to cover the edge of the light emitting structure 110. Accordingly, an inner sidewall (i.e., a sidewall facing the light emitting structure) among two sidewalls of the second insulating multilayer film structure 134 is not exposed to the outside, and an outer sidewall (i.e., a sidewall forming a side of the semiconductor light emitting device) among the two sidewalls of the second insulating multilayer film structure 134 is not exposed to the outside.

The second insulating layer 136 may be located between the insulating multilayer film structure 132 and the reflective electrode layer 144 to be described below. Accordingly, the insulating multilayer film structure 132 may be prevented from being in direct contact with the reflective electrode layer 144. The second insulating layer 136 may be disposed to cover the upper and side surfaces of the insulating multilayer film structure 132 but may not be disposed in a partial region of the insulating multilayer film structure 132 that is not in direct contact with the reflective electrode layer 144. That is, in the semiconductor light emitting device 10 of embodiments of the present disclosure, while both sidewalls and the upper surface of the first insulating multilayer film structure 133 may be covered with the second insulating layer 136 and the inner sidewall and the upper surface of the second insulating multilayer film structure 134 are covered with the second insulating layer 136, the outer sidewall of the second insulating multilayer film structure 134 may not be covered with the second insulating layer 136 and may be exposed to the outside.

In some embodiments, a portion of the second insulating layer 136 may extend to an upper surface of the first insulating layer 131. The second insulating layer 136 may include an insulating material to ensure insulation between the insulating multilayer film structure 132 and the reflective electrode layer 144. When the insulating multilayer film structure 132 includes TiO₂ and the reflective electrode layer 144 includes a metal material, such as Ag, a metal element in the reflective electrode layer 144 may migrate to the insulating multilayer film structure 132. The second insulating layer 136 may prevent the metal element of the reflective electrode layer 144 from migrating to the insulating multilayer film structure 132.

The second insulating layer 136 may include a material similar to a material of the first insulating layer 131. The second insulating layer 136 may include silicon oxide or silicon nitride such as, for example, SiO₂, SiN, SiOₓN_{y}, Si₃N₄, etc.

The reflective electrode layer 144 may be disposed on the first insulating multilayer film structure 133 and may be connected to the transparent electrode layer 140 through the first through-holes PD1 and the second through-holes PD2. For example, the reflective electrode layer 144 may include Ag, Cr, Ni, Ti, Al, Rh, Ru, or combinations thereof.

The third insulating layer 138 may cover the upper and side surfaces of the reflective electrode layer 144 and protect the reflective electrode layer 144. In addition, the third insulating layer 138 may cover a portion of the first insulating layer 131 and a portion of the second insulating layer 136. The third insulating layer 138 may be located to directly contact the first insulating layer 131 in the recess region E which is at the edge of the light emitting structure 110.

In detail, the second insulating layer 136, the reflective electrode layer 144, and the third insulating layer 138 may be stacked and disposed on the first insulating multilayer film structure 133. Alternatively, the second insulating layer 136 and the third insulating layer 138 may be stacked and disposed on the second insulating multilayer film structure 134. That is, the reflective electrode layer 144 may not be disposed on the second insulating multilayer film structure 134.

In addition, the first insulating layer 131 may have an inclined sidewall 131R that contacts the third insulating layer 138 on an inclined side surface of the mesa region M. The inclined sidewall 131R of the first insulating layer 131 may be located between the first insulating multilayer film structure 133 and the second insulating multilayer film structure 134 in the horizontal direction. Here, the first insulating multilayer film structure 133 may be disposed at a vertical level higher than a vertical level of the inclined sidewall 131R of the first insulating layer 131, and the second insulating multilayer film structure 134 may be disposed at a vertical level lower than a vertical level of the inclined sidewall 131R of the first insulating layer 131.

The third insulating layer 138 may have a first opening OPa that penetrates through the first insulating layer 131 and the third insulating layer 138 to expose the first contact region CT1 of the first conductivity-type semiconductor layer 115, and a second opening OPb exposing a third contact region CT3 of the reflective electrode layer 144. The first opening OPa may be located in the recess region E, and the second opening OPb may be located in the mesa region M.

The first connection electrode 155n may be disposed on the third insulating layer 138 and may extend onto the first contact region CT1 of the first conductivity-type semiconductor layer 115 through the first opening OPa to be electrically connected to the conductivity-type semiconductor layer 115. The first connection electrode 155n may contact the first contact region CT1 of the first conductivity-type semiconductor layer 115. In some embodiments, in order to improve contact resistance characteristics between the first connection electrode 155n and the first contact region CT1 of the first conductivity-type semiconductor layer 115, a conductive buffer layer may be located between the first connection electrode 155n and the first contact region CT1 of the conductivity-type semiconductor layer 115.

The second connection electrode 155p may be disposed on the third insulating layer 138 and may extend through the second opening OPb onto the third contact region CT3 of the reflective electrode layer 144 to be electrically connected to the reflective electrode layer 144. Accordingly, the second connection electrode 155p may be electrically connected to the second conductivity-type semiconductor layer 125 through the reflective electrode layer 144.

The first connection electrode 155n and the second connection electrode 155p may be disposed on the third insulating layer 138, may include the same material as each other, and may be apart from each other. For example, the first connection electrode 155n and the second connection electrode 155p may include one or more materials, such as Al, Au, W, Pt, Si, Ir, Ag, Cu, Ni, Ti, Cr, and alloys thereof.

In a plan view, the first connection electrode 155n may be adjacent to the first edge S1, and the second connection electrode 155p may be adjacent to the third edge S3.

The fourth insulating layer 160 may be disposed on the first connection electrode 155n and the second connection electrode 155p and may have a third opening 160a exposing a fourth contact region CT4 of the first connection electrode 155n and a fourth opening 160b exposing a fifth contact region CT5 of the second connection electrode 155p. In addition, the fourth insulating layer 160 may be stacked on the third insulating layer 138 to overlap the second insulating multilayer film structure 134.

Accordingly, at the edge of the light emitting structure 110, the outer sidewalls of the second insulating multilayer film structure 134 may be coplanar with outer sidewalls of the first insulating layer 131, the second insulating layer 136, the third insulating layer 138, and the fourth insulating layer 160. In other words, the outer sidewall of the second insulating multilayer film structure 134 and the outer sidewalls of the first insulating layer 131, the second insulating layer 136, the third insulating layer 138, and the fourth insulating layer 160 may form the side surface of the semiconductor light emitting device 10.

A first electrode pad 165n may be disposed on the fourth contact region CT4 of the first connection electrode 155n, and a second electrode pad 165p may be disposed on the fifth contact region CT5 of the second connection electrode 155p. A first solder pillar 170n may be disposed on the first electrode pad 165n, and a second solder pillar 170p may be disposed on the second electrode pad 165p. The first solder pillar 170n and the second solder pillar 170p may include a conductive material, such as Sn or AuSn.

A molding portion 172 may be formed to cover side surfaces of the first solder pillar 170n and the second solder pillar 170p. The molding portion 172 may include light-reflective powder particles, such as TiO₂ and Al₂O₃. An upper surface of the molding portion 172 may be lower than upper surfaces of the first solder pillar 170n and the second solder pillar 170p.

Semiconductor light emitting devices are known as next-generation light sources having long lifespan, low power consumption, fast response speed, and environmental friendliness compared to related art light sources, and have come to prominence as important light sources in various products, such as backlights of lighting devices and display devices. Accordingly, semiconductor light emitting devices are required to have a structure with superior light emitting characteristics and low product defects.

In the semiconductor light emitting device 10 according to embodiments of the present disclosure, a reflective structure for reflecting light, emitted from the active layer 120 in a direction away from the substrate 105, to redirect the light back toward the substrate 105 may be distributed in full over as wide a region as possible by including the first insulating multilayer film structure 133 and the second insulating multilayer film structure 134 constituting the insulating multilayer film structure 132.

In a comparative embodiment, a second insulating multilayer film structure may be located at the edge of a light emitting structure to further increase light reflection efficiency, but there is a possibility that a peeling phenomenon may occur because the second insulating multilayer film structure is exposed to the side surface of the semiconductor light emitting device.

In order to control the peeling phenomenon, the semiconductor light emitting device 10 according to embodiments of the present disclosure may include first insulating layer 131, the second insulating layer 136, the third insulating layer 138, and the fourth insulating layer 160 to more firmly surround the second insulating multilayer film structure 134. In addition, by arranging the first insulating multilayer film structure 133 and the second insulating multilayer film structure 134 to be apart in both the horizontal and vertical directions, a peeling phenomenon, that may occur in the second insulating multilayer film structure 134, does not affect the first insulating multilayer film structure 133.

Ultimately, while luminous efficiency of the semiconductor light emitting device 10 according to embodiments of the present disclosure is improved using the second insulating multilayer film structure 134, which is a distributed Bragg reflector additionally disposed at the edge of the light emitting structure 110, product defects of the semiconductor light emitting device 10 may be reduced.

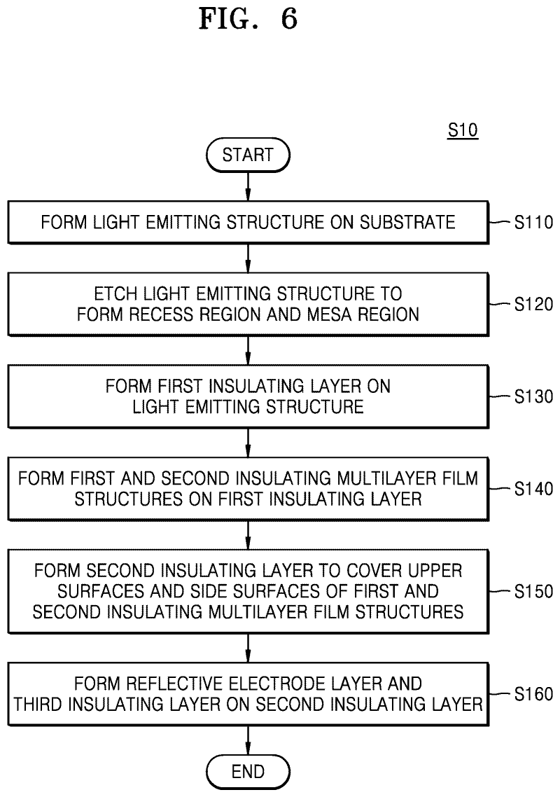

FIG. 6 is a flowchart illustrating a method S10 of manufacturing a semiconductor light emitting device according to an embodiment.

Referring to FIG. 6, the method (S10) of manufacturing a semiconductor light emitting device may include process sequences of a first operation S110, a second operation S120, a third operation S130, a fourth operation S140, a fifth operation S150, and a sixth operation S160.

In cases in which an embodiment may be implemented differently, a specific process sequence may be performed differently from the described sequence. For example, two processes described in succession may be performed substantially at the same time or may be performed in a reverse order of the described sequence.

The method (S10) of manufacturing a semiconductor light emitting device according to embodiments of the present disclosure may include a first operation S110 of forming a light emitting structure on a substrate, a second operation S120 of forming a recess region and a mesa region by etching the light emitting structure, a third operation S130 of forming a first insulating layer on the light emitting structure, a fourth operation S140 of forming first and second insulating multilayer film structures on the first insulating layer, a fifth operation S150 of forming a second insulating layer to cover upper and side surfaces of the first and second insulating multilayer film structures, and a sixth operation S160 of forming a reflective electrode layer and a third insulating layer on the second insulating layer.

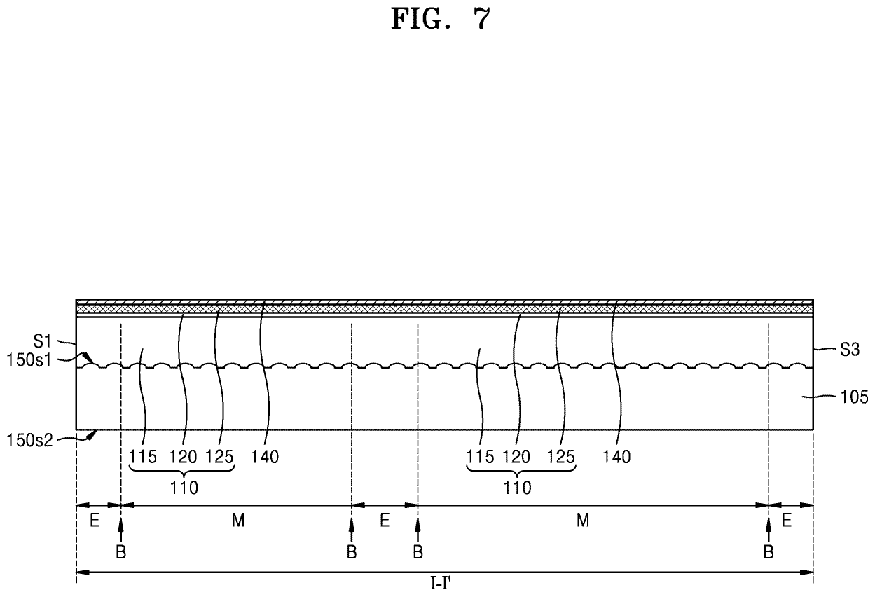

Technical features of each of the first operation S110, the second operation S120, the third operation S130, the fourth operation S140, the fifth operation S150, and the sixth operation S160 are described in detail with reference to FIGS. 7 to 14 described below.

FIGS. 7 to 14 are cross-sectional views illustrating a sequential process of a method of manufacturing a semiconductor light emitting device according to an embodiment.

Referring to FIG. 7, the light emitting structure 110 may be formed on the substrate 105.

The substrate 105 may include a material, such as sapphire, Si, SiC, MgAl₂O₄, MgO, LiAlO₂, LiGaO₂, or GaN. The substrate 105 may have the front surface 105s1 and the rear surface 105s2 located on the opposite side of the substrate 105 from the front surface 105s1.

In some embodiments, an uneven structure may be formed on the front surface 105s1 of the substrate 105. In other embodiments, forming the uneven structure on the front surface 105s1 of the substrate 105 may be omitted.

The light emitting structure 110 may be formed on the front surface 105s1 of the substrate 105. The light emitting structure 110 may be formed to include a plurality of layers using processes, such as metal organic chemical vapor deposition (MOCVD), hydrogen vapor phase epitaxy (HVPE), and molecular beam epitaxy (MBE).

For example, the light emitting structure 110 may include the first conductivity-type semiconductor layer 115, the active layer 120, and the second conductivity-type semiconductor layer 125 sequentially formed on the front surface 105s1 of the substrate 105. The first conductivity-type semiconductor layer 115 and the second conductivity-type semiconductor layer 125 may have different conductivity types. For example, the first conductivity-type semiconductor layer 115 may have an n-type conductivity type, and the second conductivity-type semiconductor layer 125 may have a p-type conductivity type.

Next, the transparent electrode layer 140 may be formed on the light emitting structure 110. The transparent electrode layer 140 may be formed on the second conductivity-type semiconductor layer 125 and electrically connected to the second conductivity-type semiconductor layer 125.

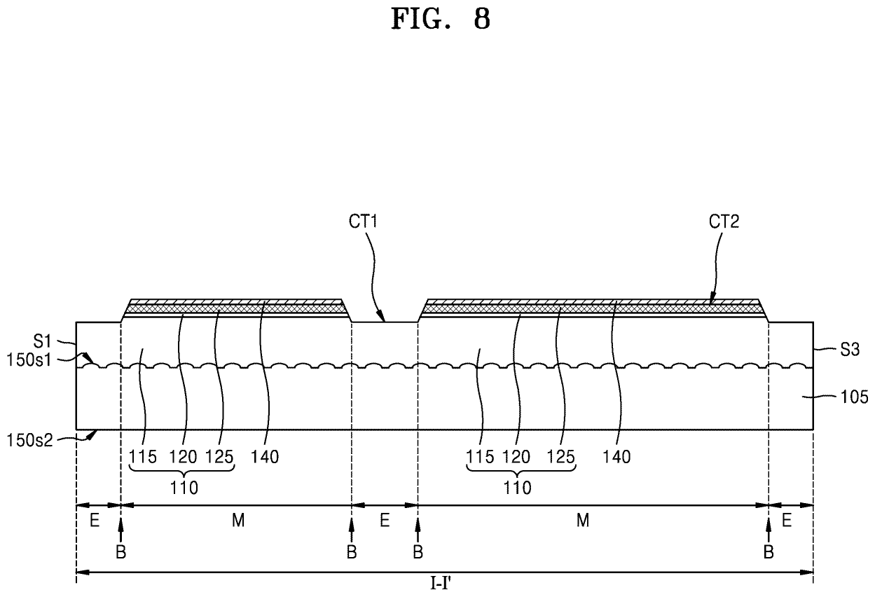

Referring to FIG. 8, portions of the transparent electrode layer 140, the second conductivity-type semiconductor layer 125, the active layer 120, and the first conductivity-type semiconductor layer 115 may be etched using a photolithography and etching process.

According to the etching process, the light emitting structure 110 may include the recess region E, in which portions of the second conductivity-type semiconductor layer 125, the active layer 120, and the first conductivity-type semiconductor layer 115 are removed, and the mesa region M therearound.

The mesa region M may be defined as a region in which the second conductivity-type semiconductor layer 125, the active layer 120, and the first conductivity-type semiconductor layer 115 are not etched. The mesa region M may have a relatively protruding shape compared to the recess region E. The recess region E may also be referred to as an etch region.

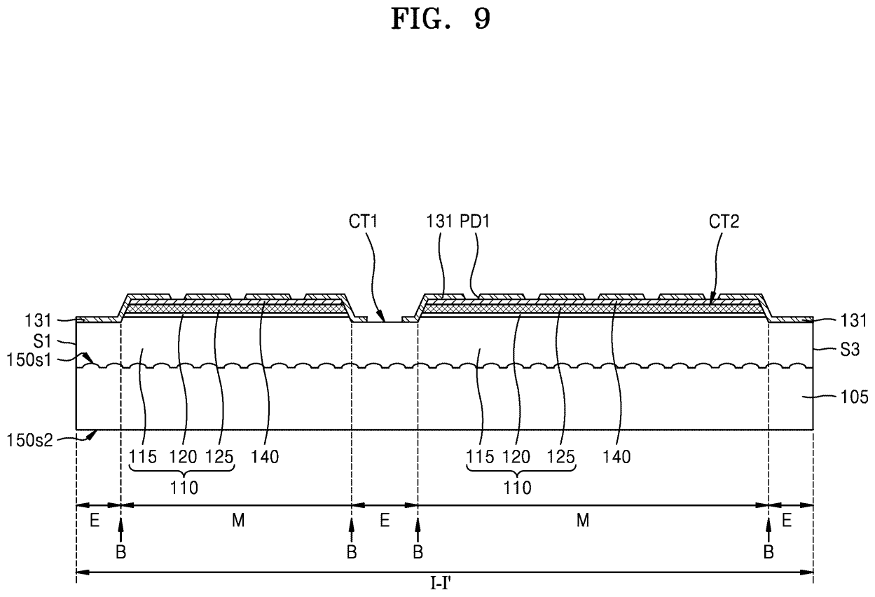

Referring to FIG. 9, the first insulating layer 131 having the first through-holes PD1 may be formed on the light emitting structure 110.

The first through-holes PD1 of the first insulating layer 131 may expose a portion of the transparent electrode layer 140. The first through-holes PD1 may be located in the mesa region M.

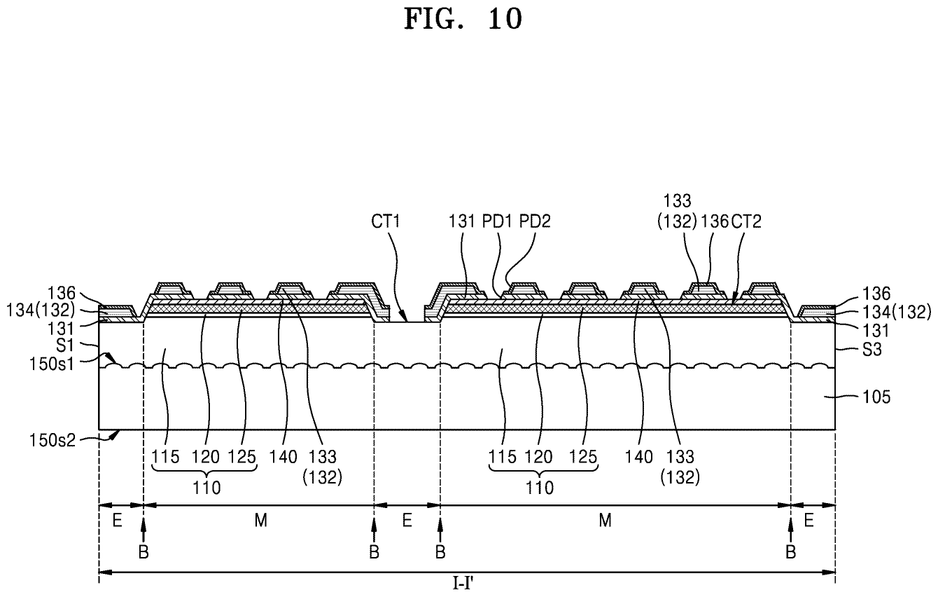

Referring to FIG. 10, the insulating multilayer film structure 132 having the second through-holes PD2 may be formed on the first insulating layer 131.

The insulating multilayer film structure 132 may include silicon oxide or silicon nitride and may include layers repeatedly formed using materials, such as SiO₂, SiN, SiOₓN_{y}, TiO₂, Si₃N₄, Al₂O₃, TiN, AlN, ZrO₂, TiAlN, TiSiN, etc. This process may be performed using processes, such as MOCVD, HVPE, MBE, etc.

The insulating multilayer film structure 132 may be provided as a structure in which layers having different refractive indices are alternately stacked. This insulating multilayer film structure 132 may be provided as a distributed Bragg reflector by appropriately adjusting the refractive indices and thicknesses of the alternately stacked layers.

According to embodiments of the present disclosure, the insulating multilayer film structure 132 may include the first insulating multilayer film structure 133 and the second insulating multilayer film structure 134. The first insulating multilayer film structure 133 may be disposed to cover a portion of the first insulating layer 131 in the mesa region M. The second insulating multilayer film structure 134 may be disposed on the first insulating layer 131 in the recess region E, which is at an edge of the light emitting structure 110.

The second through-holes PD2 may be arranged to correspond to the first through-holes PD1. The size of each of the second through-holes PD2 may be greater than a size of each of the first through-holes PD1.

Next, the second insulating layer 136 may be formed to cover the upper and side surfaces of the insulating multilayer film structure 132.

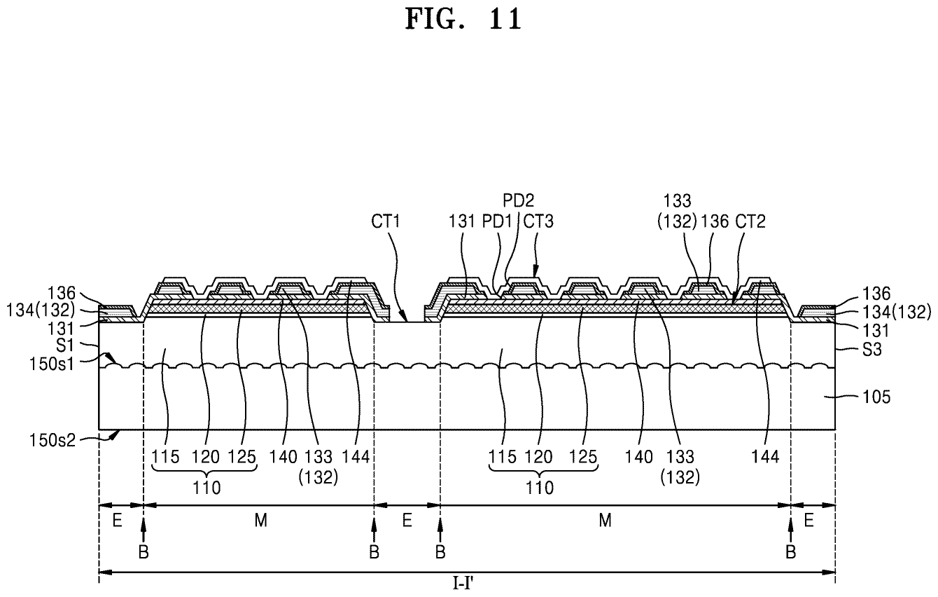

Referring to FIG. 11, the reflective electrode layer 144 may be formed on the second insulating layer 136.

The reflective electrode layer 144 may be formed in the mesa region M. The reflective electrode layer 144 may be disposed not to directly contact the insulating multilayer film structure 132 due to the second insulating layer 136.

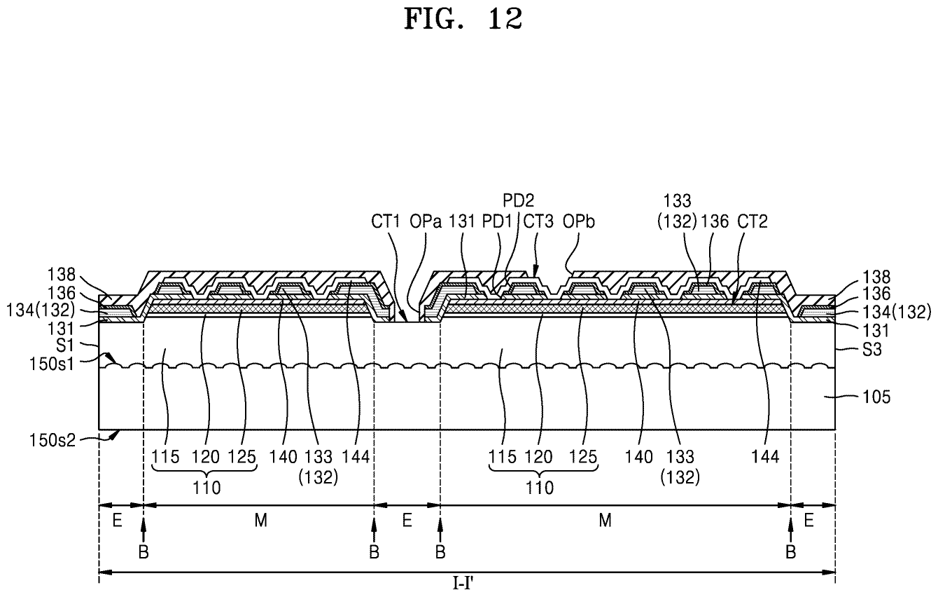

Referring to FIG. 12, the third insulating layer 138 may be formed on the reflective electrode layer 144.

The third insulating layer 138 may cover the upper and side surfaces of the reflective electrode layer 144 and a portion of the first insulating layer 131. The third insulating layer 138 may cover a portion of the second insulating layer 136 adjacent to the reflective electrode layer 144.

The third insulating layer 138 may be formed by, for example, forming a photoresist pattern that exposes a region in which the third insulating layer 138 is to be formed and then performing a physical vapor deposition process, such as sputtering.

The first opening OPa may be provided that penetrates through the first insulating layer 131 and the third insulating layer 138 and exposes a portion of the first conductivity-type semiconductor layer 115 in the recess region E, and the second opening OPb may be provided that penetrates through the third insulating layer 138 and exposing a portion of the reflective electrode layer 144 in the mesa region M.

The surface of the first conductivity-type semiconductor layer 115 exposed by the first opening OPa may be referred to as the first contact region CT1, and the surface of the reflective electrode layer 144 exposed by the second opening OPb may be referred to as the third contact region CT3.

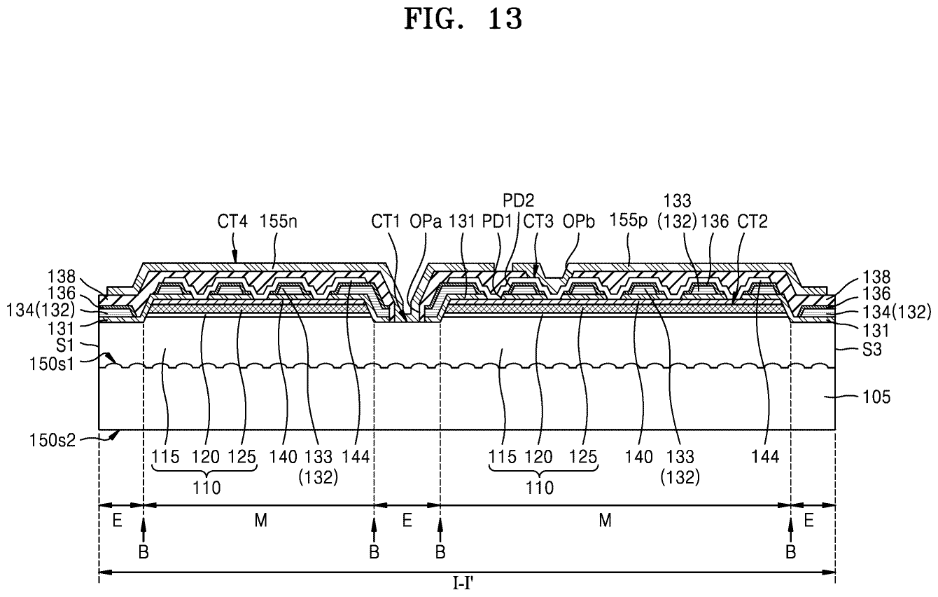

Referring to FIG. 13, the first connection electrode 155n and the second connection electrode 155p may be formed on the substrate 105 such as, for example, on the third insulating layer 138.

The forming of the first connection electrode 155n and the second connection electrode 155p may include forming a conductive material layer on the substrate 105 (e.g., on the third insulating layer 138) and etching a portion of the conductive material layer using a photolithography and etching process. Because the first connection electrode 155n and the second connection electrode 155p are formed through the same process, the first connection electrode 155n and the second connection electrode 155p may be formed with the same material. The first connection electrode 155n and the second connection electrode 155p may be formed to have the same thickness.

The first connection electrode 155n may be electrically connected to the first contact region CT1 of the first conductivity-type semiconductor layer 115. The second connection electrode 155p may be electrically connected to the third contact region CT3 of the reflective electrode layer 144.

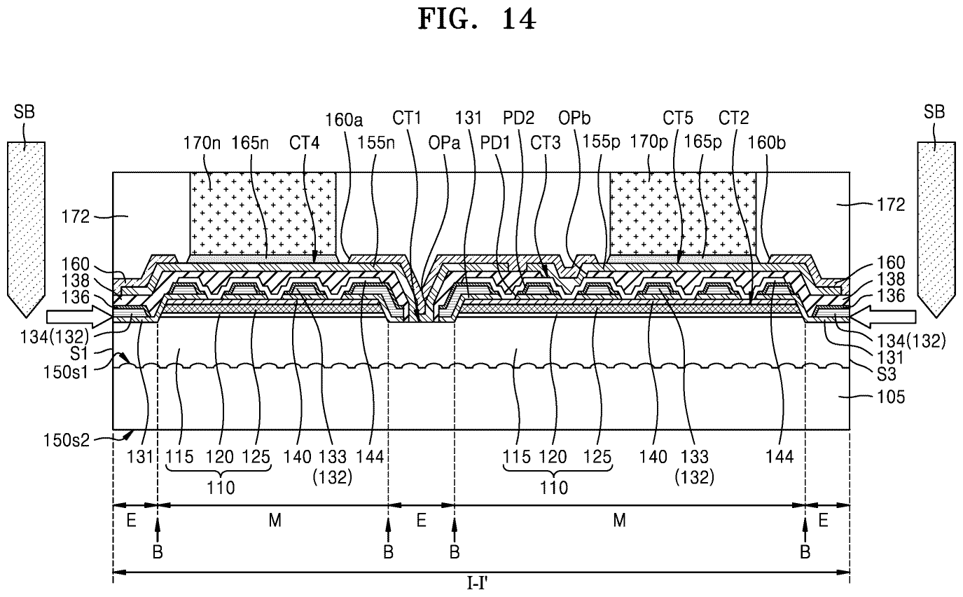

Referring to FIG. 14, the fourth insulating layer 160 having the third opening 160a and the fourth opening 160b may be formed on the substrate 105 such as, for example, on the first connection electrode 155n and the second connection electrode 155p.

The third opening 160a of the fourth insulating layer 160 may expose a partial region of the first connection electrode 155n, and the fourth opening 160b of the fourth insulating layer 160 may expose a partial region of the second connection electrode 155p.

The partial region of the first connection electrode 155n exposed by the third opening 160a of the fourth insulating layer 160 may be referred to as the fourth contact region CT4, and the partial region of the second connection electrode 155p exposed by the fourth opening 160b of the fourth insulating layer 160 may be referred to as the fifth contact region CT5.

The first electrode pad 165n and the second electrode pad 165p may be formed on the substrate 105 such as, for example, on the fourth insulating layer 160. The first electrode pad 165n may be formed on the fourth contact region CT4 of the first connection electrode 155n, and the second electrode pad 165p may be formed on the fifth contact region CT5 of the second connection electrode 155p. The first electrode pad 165n and the second electrode pad 165p may be formed using under bump metallurgy (UBM). In some embodiments, the number and arrangement structure of the first electrode pad 165n and the second electrode pad 165p may vary.

The first solder pillar 170n and the second solder pillar 170p may be formed on the substrate 105. In some embodiments, each of the first solder pillar 170n and the second solder pillar 170p may be formed in plural. The first solder pillar 170n may be formed on the first electrode pad 165n, and the second solder pillar 170p may be formed on the second electrode pad 165p.

The molding portion 172 may be formed to cover the side surfaces of the first solder pillar 170n and the second solder pillar 170p. The molding portion 172 may include light-reflective powder particles, such as TiO₂ and Al₂O₃.

The semiconductor light emitting device 10 manufactured according to the manufacturing process may be cut by a sawing blade SB to be completed as a package-type product. During a cutting process of the sawing blade SB, there is a possibility that a peeling phenomenon may occur in the second insulating multilayer film structure 134 exposed to the side surface of the semiconductor light emitting device 10.

In order to control the peeling phenomenon caused by the sawing blade SB, the first insulating layer 131, the second insulating layer 136, the third insulating layer 138, and the fourth insulating layer 160 are formed to more firmly surround the second insulating multilayer film structure 134. In addition, because the first insulating multilayer film structure 133 and the second insulating multilayer film structure 134 are formed to be apart from each other in both the horizontal and vertical directions, a peeling phenomenon that may occur in the second insulating multilayer film structure 134 may not affect the first insulating multilayer film structure 133.

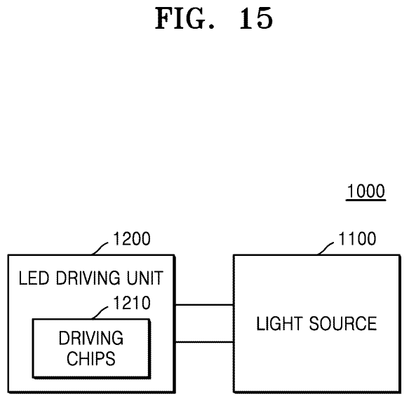

FIG. 15 is a block diagram illustrating a configuration of a light source module 1000 including a semiconductor light emitting device according to an embodiment.

Referring to FIG. 15, the light source module 1000 may include a light source 1100 and a light-emitting diode (LED) driving unit 1200.

The light source 1100 may include the semiconductor light emitting device 10 described above with reference to FIGS. 1 to 5.

The LED driving unit 1200 may be connected to a power supply, and the power supply may generate an input voltage for the light source 1100 to operate and provide the input voltage to the light source 1100. In some embodiments, when the light source module 1000 is a headlamp for an automobile, the power supply may be a battery mounted on the automobile. In some embodiments, when the light source module 1000 is a home or business lighting fixture, the light source module 1000 may include an alternating current (AC) power source that generates an AC voltage, a rectifier circuit that rectifies the AC voltage to generate a direct current (DC) voltage, and a voltage regulator circuit, etc.

The LED driving unit 1200 may include a plurality of driving chips 1210. Each of the plurality of driving chips 1210 may be implemented as an integrated circuit chip. The plurality of driving chips 1210 may drive the light source 1100.

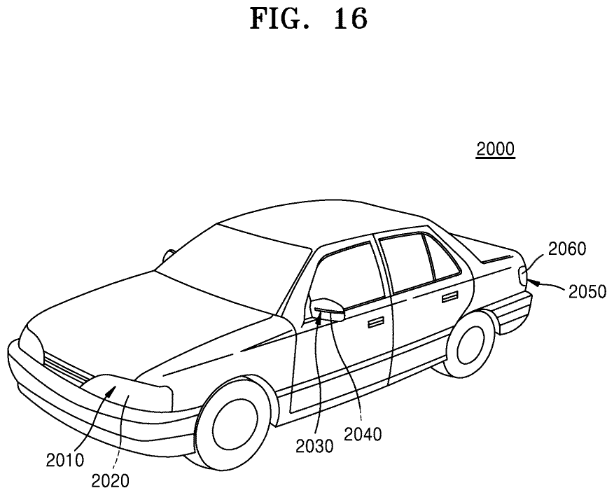

FIG. 16 is a perspective view illustrating a lighting device including a semiconductor light emitting device according to an embodiment.

Referring to FIG. 16, a head lamp module 2020 may be installed in the head lamp unit 2010 of a car, a side mirror lamp module 2040 may be installed in an external side mirror unit 2030, and a tail lamp module 2060 may be installed within the tail lamp unit 2050.

Here, at least one from among the head lamp module 2020, the side mirror lamp module 2040, and the tail lamp module 2060 may include the semiconductor light emitting device 10 described above with reference to FIGS. 1 to 5.

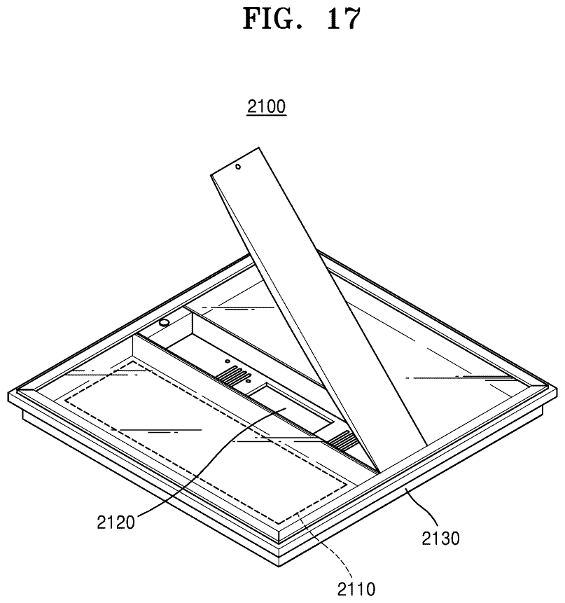

FIG. 17 is a perspective view illustrating a flat lighting device 2100 including a light source module 2110 including a semiconductor light emitting device according to an embodiment.

Referring to FIG. 17, the flat lighting device 2100 may include the light source module 2110, a power supply device 2120, and a housing 2130.

The light source module 2110 may include the semiconductor light emitting device 10 described above with reference to FIGS. 1 to 5. The light source module 2110 may have a flat shape overall.

The power supply device 2120 may be configured to supply power to the light source module 2110. The housing 2130 may include an accommodating space to accommodate the light source module 2110 and the power supply device 2120 therein and may have a hexahedral shape with one side open, but is not limited thereto. The light source module 2110 may be located to emit light through one open side of the housing 2130.

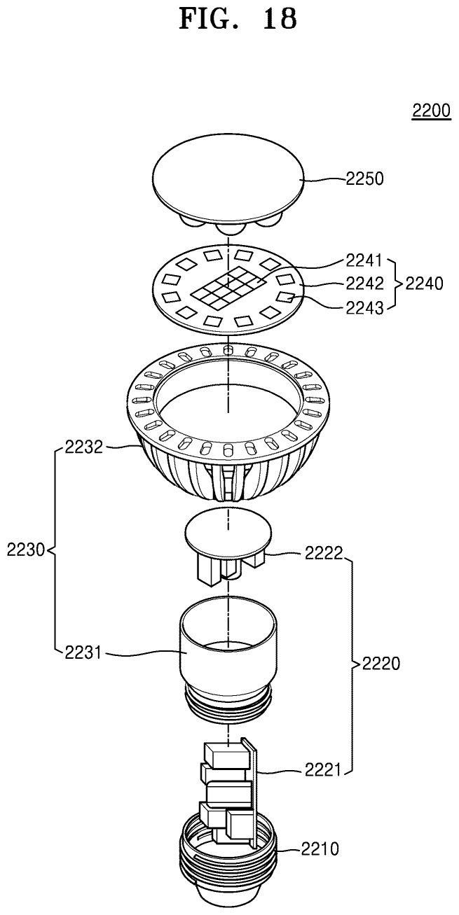

FIG. 18 is an exploded perspective view illustrating a lighting device 2200 including a light source module including a semiconductor light emitting device according to an embodiment.

Referring to FIG. 18, the lighting device 2200 may include a socket 2210, a power supply unit 2220, a heat dissipation unit 2230, a light source module 2240, and an optical unit 2250.

The socket 2210 may be configured to replace a lighting device of the related art. Power supplied to the lighting device 2200 may be applied through the socket 2210. The power supply unit 2220 may include a first power supply unit 2221 and a second power supply unit 2222 that are manufactured separately and may be assembled. The heat dissipation unit 2230 may include an internal heat dissipation unit 2231 and an external heat dissipation unit 2232. The internal heat dissipation unit 2231 may be directly connected to the light source module 2240 and/or the power supply unit 2220, through which heat may be transferred to the external heat dissipation unit 2232. The optical unit 2250 may include an internal optical unit and an external optical unit, and may be configured to evenly distribute light emitted from the light source module 2240.

The light source module 2240 may receive power from the power supply unit 2220 and emit light to the optical unit 2250. The light source module 2240 may include at least one light emitting device package 2241, a circuit board 2242, and a controller 2243. The controller 2243 may store driving information of the light emitting device package 2241. The light source module 2240 may include the semiconductor light emitting device 10 described above with reference to FIGS. 1 to 5.

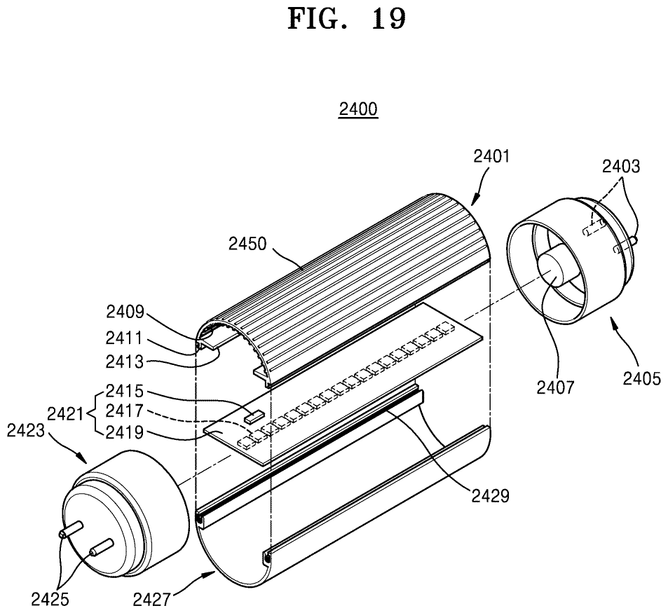

FIG. 19 is an exploded perspective view illustrating a bar-type lighting device 2400 including a light source module including a semiconductor light emitting device according to an embodiment.

Referring to FIG. 19, the lighting device 2400 may include a heat dissipation member 2401, a cover 2427, a light source module 2421, a first socket 2405, and a second socket 2423.

A plurality of heat dissipation fins 2450 and 2409 may be formed in an uneven shape on an inner and/or outer surface of the heat dissipation member 2401, and the heat dissipation fins 2450 and 2409 may be designed to have various shapes and spacing. A protruding support 2413 is formed inside the heat dissipation member 2401. The light source module 2421 may be fixed to the protruding support 2413. Locking protrusions 2411 may be formed at both ends of the heat dissipation member 2401.

A locking groove 2429 may be formed in the cover 2427, and the locking protrusion 2411 of the heat dissipation member 2401 may be coupled to the locking groove 2429 in a hook coupling structure. The positions at which the locking groove 2429 and the locking protrusion 2411 are formed may be interchanged.

The light source module 2421 may include a printed circuit board 2419, a light source 2417, and a controller 2415. The controller 2415 may store driving information of the light source 2417. Circuit wirings for operating the light source 2417 are formed on the printed circuit board 2419. In addition, components for operating the light source 2417 may be included. The light source module 2421 may include the semiconductor light emitting device 10 described above with reference to FIGS. 1 to 5.

A pair of sockets including a first socket 2405 and a second socket 2423 has a structure coupled to both ends of a cylindrical cover unit including a heat dissipation member 2401 and a cover 2427. For example, the first socket 2405 may include an electrode terminal 2403 and a power supply 2407, and a dummy terminal 2425 may be located in the second socket 2423. In addition, an optical sensor and/or a communication module may be built into any one from among the first socket 2405 and the second socket 2423.

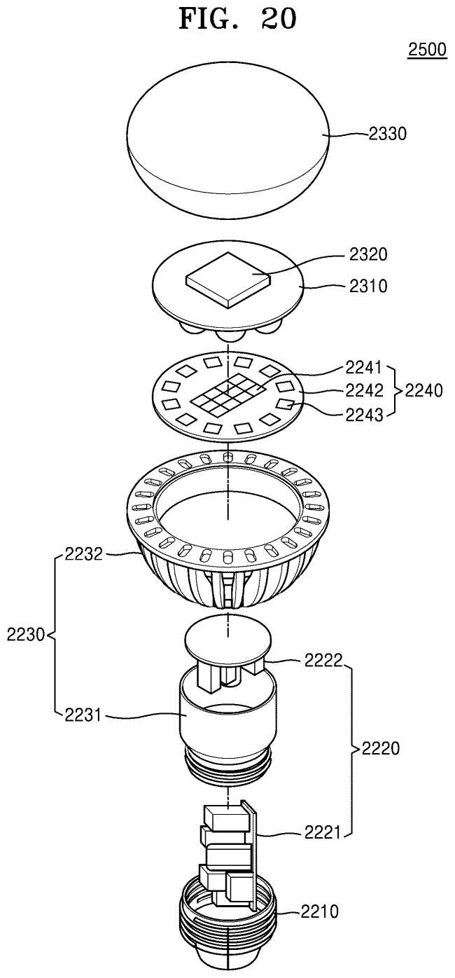

FIG. 20 is an exploded perspective view illustrating a lighting device 2500 including a light source module including a semiconductor light emitting device according to an embodiment.

Referring to FIG. 20, the lighting device 2500, having a configuration generally similar to the configuration of the lighting device 2200 illustrated in FIG. 18, includes a reflector 2310 and a communication module 2320 disposed on top of a light source module 2240.

The reflector 2310 may evenly spread light from a light source laterally and backwardly, thereby reducing glare. The communication module 2320 may be mounted on top of the reflector 2310. Home-network communication may be implemented through the communication module 2320. For example, the communication module 2320 may be a wireless communication module using Zigbee, WiFi, or LiFi, and through a smartphone or a wireless controller, lighting installed inside and outside the home, such as ON/OFF, brightness control, etc., of the lighting device may be controlled or electronic products and car systems inside and outside the home, such as televisions, refrigerators, air-conditioners, door locks, and cars, may be controlled. The reflector 2310 and the communication module 2320 may be covered by a cover portion 2330.

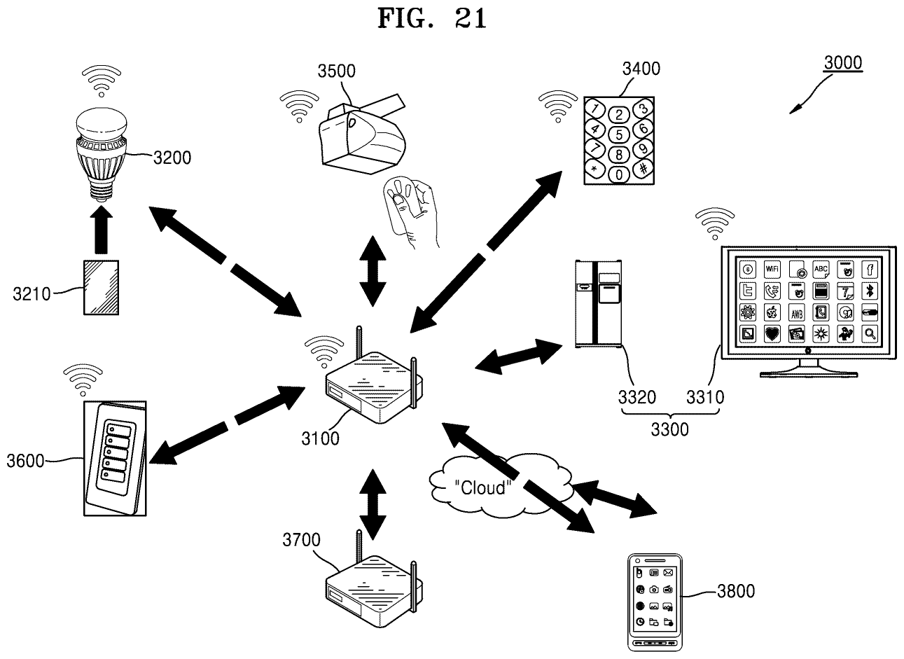

FIG. 21 is a schematic diagram illustrating a network system 3000 for controlling an indoor lighting including a light source module including a semiconductor light emitting device according to an embodiment.

Referring to FIG. 21, the network system 3000 may be a complex smart lighting-network system that combines lighting technology using light emitting devices, such as LEDs, Internet of Things (IoT) technology, and wireless communication technology.

The network system 3000 may be implemented using various lighting devices and wired and wireless communication devices, or may be implemented based on an IoT environment so that various information may be collected/processed and provided to users.

An LED lamp 3200 included in the network system 3000 may control lighting thereof upon receiving information on a surrounding environment from a gateway 3100 and may serve to determine and control an operating state of a plurality of other devices included in the IoT environment based on a function, such as visible light communication of the LED lamp 3200.

The LED lamp 3200 may include the semiconductor light emitting device 10 described above with reference to FIGS. 1 to 5. The LED lamp 3200 may be connected to communicate with the gateway 3100 by a wireless communication protocol, such as WiFi, Zigbee, or LiFi, and to this end, the LED LAMP 3200 may have at least one lamp communication module 3210.

When the network system 3000 is applied to a home, the plurality of other devices may include home appliances 3300, digital door locks 3400, garage door locks 3500, a lighting switch 3600 installed on a wall, etc., a router 3700 for wireless communication network relay, and a mobile device 3800, such as a smartphone, tablet, or laptop computer.

In the network system 3000, the LED lamp 3200 may determine an operating state of various types of the plurality of other devices using a wireless communication network (Zigbee, WiFi, LiFi, etc.) installed in the home or automatically adjust the illuminance of the LED lamp 3200 itself according to a surrounding environment/situation. In addition, the plurality of other devices included in the network system 3000 may be controlled using LiFi communication using visible light emitted from the LED lamp 3200.

The LED lamp 3200 may automatically adjust the illuminance of the LED lamp 3200 based on a surrounding environment transferred from the gateway 3100 through the lamp communication module 3210 or surrounding environment information collected from a sensor mounted on the LED lamp 3200.

For example, the lighting brightness of the LED lamp 3200 may be automatically adjusted according to the type of program being broadcast on the television 3310 or the brightness of a screen. To this end, the LED lamp 3200 may receive operation information of the television 3310 from the lamp communication module 3210 connected to the gateway 3100. The lamp communication module 3210 may be integrated with a sensor and/or controller included in the LED lamp 3200.

For example, when a certain period of time has elapsed after the digital door lock 3400 was locked while no one is in the home, all of the turned-on LED lamps 3200 may be turned off to prevent electricity waste. Alternatively, when a security mode is set through the mobile device 3800, etc., if the digital door lock 3400 is locked without anyone in the home, the LED lamp 3200 may be kept in the turn-on state.

The operation of the LED lamp 3200 may be controlled according to the surrounding environment collected through various sensors connected to the network system 3000. For example, when the network system 3000 is implemented within a building, a lighting, a location sensor, and a communication module within the building may be combined to collect location information of people within the building, turn lightings on or off, or provide the collected information in real time, thereby enabling facility management or efficient use of idle space.

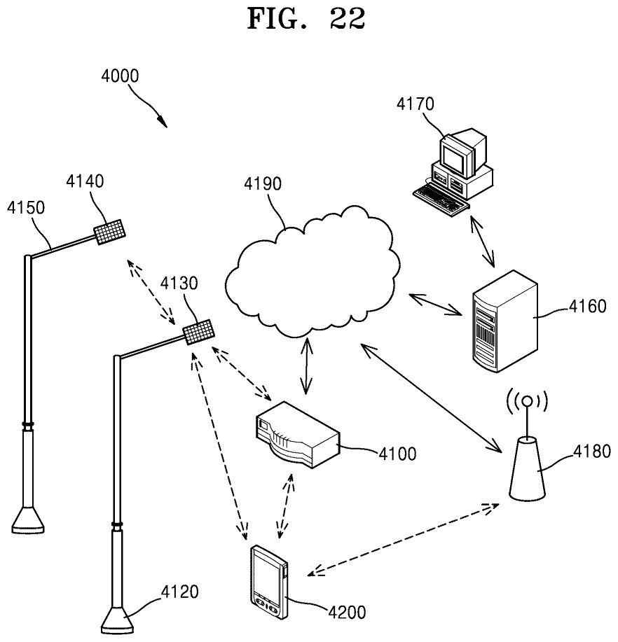

FIG. 22 is a schematic diagram illustrating a network system 4000 including a light source module including a semiconductor light emitting device according to an embodiment.

Referring to FIG. 22, the network system 4000 may include a communication connection device 4100, a plurality of lighting fixtures 4120 and 4150 installed at preset intervals and connected to enable communication with the communication connection device 4100, a server 4160, a computer 4170 for managing the server 4160, a communication base station 4180, a communication network 4190 connecting communication-available equipment, and a mobile device 4200.

Each of the plurality of lighting fixtures 4120 and 4150 installed in an open external space, such as a street or park, may include smart engines (e.g., a smart engine 4130 and the smart engine 4140). The smart engines may include a light emitting device for emitting light, a driver for driving the light emitting device, a sensor for collecting information on a surrounding environment, and a communication module. The smart engines (e.g., the smart engine 4130 and the smart engine 4140) may include the semiconductor light emitting device 10 described above with reference to FIGS. 1 to 5.

The smart engines may communicate with other surrounding equipment according to communication protocols, such as WiFi, Zigbee, and LiFi using the communication module. The smart engine 4130 may be connected to communicate with the smart engine 4140, and WiFi expansion technology (WiFi Mesh) may be applied to communication between the smart engine 4130 and the smart engine 4140. At least one smart engine (e.g., the smart engine 4130) may be connected to the communication connection device 4100 connected to the communication network 4190 through wired/wireless communication.

The communication connection device 4100 is an access point (AP) capable of wired/wireless communication and may mediate communication between the communication network 4190 and other equipment. According to an example embodiment, the communication connection device 4100 may be connected to the communication network 4190 by at least one of wired and wireless methods and may be mechanically received inside one of the lighting fixtures 4120 and 4150.

The communication connection device 4100 may be connected to the mobile device 4200 through a communication protocol, such as WiFi. A user of the mobile device 4200 may receive surrounding environment information, for example, surrounding traffic information, weather information, etc., collected by the plurality of smart engines (e.g., the smart engine 4130 and the smart engine 4140) through the communication connection device 4100 connected to the smart engine (e.g., the smart engine 4130) of the adjacent surrounding lighting fixture (e.g., the light fixture 4120). The mobile device 4200 may be connected to the communication network 4190 via the communication base station 4180 through a wireless cellular communication method, such as 3G, 4G, or 5G.

The server 4160 connected to the communication network 4190 may receive information collected by the smart engine 4130 and the smart engine 4140 respectively mounted on the lighting fixtures 4120 and 4150 and simultaneously control an operating state of each of the lighting fixtures 4120 and 4150. The server 4160 may be connected to the computer 4170 that provides a management system, and the computer 4170 may run software that may monitor and manage an operating state of the smart engines (e.g., the smart engine 4130 and the smart engine 4140).

While non-limiting example embodiments have been particularly shown and described, it will be understood that various changes in form and details may be made therein without departing from the spirit and scope of the present disclosure.

What is claimed is:

1. A semiconductor light emitting device comprising:
a substrate;
a light emitting structure comprising a first conductivity-type semiconductor layer, an active layer, and a second conductivity-type semiconductor layer sequentially stacked on the substrate;
a transparent electrode layer on the second conductivity-type semiconductor layer;
a first insulating layer on the transparent electrode layer and including a plurality of first through-holes;
a first distributed Bragg reflector on the first insulating layer and including a plurality of second through-holes overlapping the plurality of first through-holes, wherein the first distributed Bragg reflector is apart from an edge of the light emitting structure;
a second distributed Bragg reflector at the edge of the light emitting structure;
a second insulating layer on the first distributed Bragg reflector and the second distributed Bragg reflector; and
a reflective electrode layer on the second insulating layer such as to overlap the first distributed Bragg reflector, the reflective electrode layer connected to the transparent electrode layer through the plurality of first through-holes and the plurality of second through-holes.

2. The semiconductor light emitting device of claim 1, wherein each of the first distributed Bragg reflector and the second distributed Bragg reflector comprises an insulating multilayer film structure comprising insulating films, having different refractive indices from each other, that are alternately stacked.

3. The semiconductor light emitting device of claim 1, wherein the second insulating layer is on two sidewalls and an upper surface of the first distributed Bragg reflector,
wherein the second insulating layer is on an inner sidewall and an upper surface of the second distributed Bragg reflector, and
wherein an outer sidewall of the second distributed Bragg reflector is exposed from the second insulating layer.

4. The semiconductor light emitting device of claim 3, wherein the first insulating layer is on a lower surface of each of the first distributed Bragg reflector and the second distributed Bragg reflector.

5. The semiconductor light emitting device of claim 1, wherein a vertical level of the first distributed Bragg reflector is higher than a vertical level of the second distributed Bragg reflector.

6. The semiconductor light emitting device of claim 5, wherein the first distributed Bragg reflector is above the light emitting structure, and
wherein at least a portion the second distributed Bragg reflector is at a same vertical level as a vertical level of a portion of the light emitting structure.

7. The semiconductor light emitting device of claim 1, further comprising a third insulating layer on the second insulating layer and the reflective electrode layer.

8. The semiconductor light emitting device of claim 7, wherein the second insulating layer, the reflective electrode layer, and the third insulating layer are stacked on the first distributed Bragg reflector, and
wherein the second insulating layer and the third insulating layer are stacked on the second distributed Bragg reflector.

9. The semiconductor light emitting device of claim 8, further comprising:
a fourth insulating layer in contact with the third insulating layer at the edge of the light emitting structure,
wherein the fourth insulating layer is stacked on the third insulating layer such as to overlap the second distributed Bragg reflector.

10. The semiconductor light emitting device of claim 9, wherein an outer sidewall of the second distributed Bragg reflector is coplanar with outer sidewalls of the first insulating layer, the second insulating layer, the third insulating layer, and the fourth insulating layer at the edge of the light emitting structure.

11. A semiconductor light emitting device comprising:
a substrate;
a light emitting structure comprising a first conductivity-type semiconductor layer, an active layer, and a second conductivity-type semiconductor layer that are stacked on the substrate, the light emitting structure further comprising a recess region in which portions of the first conductivity-type semiconductor layer, the active layer, and the second conductivity-type semiconductor layer are removed and a mesa region adjacent to the recess region;
a transparent electrode layer on the second conductivity-type semiconductor layer;
a first insulating layer on the transparent electrode layer and including a plurality of first through-holes in the mesa region;
a first insulating multilayer film structure in the mesa region and on the first insulating layer, the first insulating multilayer film structure including a plurality of second through-holes overlapping the plurality of first through-holes;
a second insulating multilayer film structure on the first insulating layer in the recess region;
a second insulating layer covering an upper surface and side surfaces of the first insulating multilayer film structure and an upper surface and a side surface of the second insulating multilayer film structure; and
a reflective electrode layer on the second insulating layer such as to overlap the first insulating multilayer film structure, the reflective electrode layer connected to the transparent electrode layer through the plurality of first through-holes and the plurality of second through-holes.

12. The semiconductor light emitting device of claim 11, wherein each of the first insulating multilayer film structure and the second insulating multilayer film structure is a distributed Bragg reflector comprising at least one first insulating film, having a first refractive index, and at least one second insulating film, having a second refractive index different from the first refractive index, that are alternately stacked.

13. The semiconductor light emitting device of claim 11, further comprising:
a third insulating layer on the second insulating layer and the reflective electrode layer,
wherein the first insulating layer comprises an inclined sidewall that contacts the third insulating layer at an inclined side surface of the mesa region.

14. The semiconductor light emitting device of claim 13, wherein the inclined sidewall of the first insulating layer is between the first insulating multilayer film structure and the second insulating multilayer film structure in a horizontal direction.

15. The semiconductor light emitting device of claim 14, wherein a vertical level of the first insulating multilayer film structure is higher than a vertical level of the inclined sidewall of the first insulating layer, and
wherein a vertical level of the second insulating multilayer film structure is lower than the vertical level of the inclined sidewall of the first insulating layer.

16. A semiconductor light emitting device comprising:
a substrate;
a light emitting structure comprising a first conductivity-type semiconductor layer, an active layer, and a second conductivity-type semiconductor layer that are stacked on the substrate, the light emitting structure further comprising a recess region in which portions of the first conductivity-type semiconductor layer, the active layer, and the second conductivity-type semiconductor layer are removed and a mesa region adjacent to the recess region;
a transparent electrode layer on the second conductivity-type semiconductor layer;
a first insulating layer on the transparent electrode layer and including a plurality of first through-holes;
a first distributed Bragg reflector on the first insulating layer and including a plurality of second through-holes overlapping the plurality of first through-holes, wherein the first distributed Bragg reflector is apart from an edge of the light emitting structure;
a second distributed Bragg reflector on the first insulating layer and at the edge of the light emitting structure;
a second insulating layer on the first distributed Bragg reflector and the second distributed Bragg reflector;
a reflective electrode layer on the second insulating layer such as to overlap the first distributed Bragg reflector, the reflective electrode layer connected to the transparent electrode layer through the plurality of first through-holes and the plurality of second through-holes;
a third insulating layer on the second insulating layer and the reflective electrode layer;
a first connection electrode contacting and electrically connected to the first conductivity-type semiconductor layer through the first insulating layer, the second insulating layer, and the third insulating layer; and
a second connection electrode contacting the reflective electrode layer and electrically connected to the second conductivity-type semiconductor layer through the third insulating layer.

17. The semiconductor light emitting device of claim 16, further comprising:
a first electrode pad connected to the first connection electrode;
a second electrode pad connected to the second connection electrode;
a first solder pillar connected to the first electrode pad;
a second solder pillar connected to the second electrode pad; and
a molding portion on a side surface of the first solder pillar and a side surface of the second solder pillar.

18. The semiconductor light emitting device of claim 16, wherein the first insulating layer is on a lower surface of each of the first distributed Bragg reflector and the second distributed Bragg reflector,
wherein the second insulating layer is on two sidewalls and an upper surface of the first distributed Bragg reflector,
wherein the second insulating layer is on an inner sidewall and an upper surface of the second distributed Bragg reflector layer, and
wherein an outer sidewall of the second distributed Bragg reflector layer is exposed from the second insulating layer.

19. The semiconductor light emitting device of claim 16, wherein a vertical level of the first distributed Bragg reflector is higher than a vertical level of the second distributed Bragg reflector,
wherein the first distributed Bragg reflector is in the mesa region, and
wherein the second distributed Bragg reflector is in the recess region.

20. The semiconductor light emitting device of claim 16, wherein the second insulating layer, the reflective electrode layer, and the third insulating layer are stacked on the first distributed Bragg reflector, and
wherein the second insulating layer and the third insulating layer are stacked on the second distributed Bragg reflector.
